(19) United States
(12) Patent Application Publication
(10) Pub. No.: US 2010/0067847 A1
(43) Pub. Date: Mar. 18, 2010

(54) TUNABLE OPTOFLUIDIC DEVICE AND METHOD OF ITS FABRICATION

(75) Inventors: Uriel LEVY, Kiriat Ono (IL); Romi SHAMAI, Jerusalem (IL)

Correspondence Address: OLIFF & BERRIDGE, PLC, P.O. BOX 320850, ALEXANDRIA, VA, 22320-4850, US

(73) Assignee: Yissum Research Development Company of the Hebrew University of Jerusalem, Ltd., Jerusalem (IL)

(21) Appl. No.: 12/543,166

(22) Filed: Aug. 18, 2009

Related U.S. Application Data
(60) Provisional application No. 61/089,636, filed on Aug. 18, 2008.

(51) Int. Cl. G02B 6/12; G02B 6/13; C23C 16/513; C23C 14/34

(52) U.S. Cl. 385/14; 427/579; 204/192.29

(57) ABSTRACT

An integrated structure and method of its fabrication are presented. The integrated structure comprises at least one waveguide; at least one fluid chamber; and an electrode assembly. The fluid chamber is associated with said at least one waveguide and configured and operable to selectively allow one or more droplets of said fluid from the fluid chamber to access at least a portion of the waveguide thereby selectively creating one or more fluid-waveguide interfaces and affecting the effective refractive index of the waveguide and light coupling at said one or more interface. The electrode assembly is configured and operable to induce an electric field within said at least one fluid chamber to affect the fluid-waveguide interface, thereby affecting light propagation in said waveguide and accordingly affecting optical properties of the integrated structure.

### FIELD OF THE INVENTION

This invention is generally in the field of tunable optofluidic devices and relates to an integrated electro-optical device and method of its fabrication.

### REFERENCES

The following references are considered to be pertinent for the purpose of understanding the background of the present invention:
1. U. Levy and R. Shamai, “Tunable optofluidic devices,” Microfluid Nanofluid 4, 97-105 (2007).
2. L. Pang, U. Levy, K. Campbell, A. Groisman, Y. Fainman, “A set of two orthogonal adaptive cylindrical lenses in a monolith elastomer device,” Opt. Express 13, 9003-9013 (2005).
3. K. Campbell, U. Levy, Y. Fainman, A. Groisman, “Pressure-driven devices with lithographically fabricated composite epoxy-elastomer membranes,” Appl. Phys. Lett. 89, 154105-154107 (2006).
4. K. Campbell, A. Groisman, U. Levy, L. Pang, S. Mookherjea, D. Psaltis, Y. Fainman, “A microfluidic 2×2 optical switch,” Appl. Phys. Lett. 85, 6119-6121 (2004).
5. U. Levy, K. Campbell, A. Groisman, S. Mookherjea, Y. Fainman, “On-chip microfluidic tuning of an optical microring resonator,” Appl. Phys. Lett. 88, 111107-111109 (2006).
6, J. C. Galas, J. Torres, M. Belotti, Q. Kou, Y. Chen, “Microfluidic tunable dye laser with integrated mixer and ring resonator,” Appl. Phys. Lett. 86, 264101-264103 (2005).
7. D. Erickson, T. Rockwood, T. Emery, A. Scherer, D. Psaltis, “Nanofluidic tuning of photonic crystal circuits,” Opt. Lett. 31, 59-61 (2006).
8. D. B. Wolfe, R. S. Conroy, P. Garstecki, B. T. Mayers, M. A, Fischbach, K. E. Paul, M. Prentiss, G. M. Whitesides, “Dynamic control of liquid-core/liquid-cladding optical waveguides,” PNAS 101, 12434-12438 (2004).
9. F. Mugele and J-C Baret, “Electrowetting: from basics to applications,” J. Phys.: Condens. Matter 17, R705-R774 (2005).
10. N. R. Smith, D. C. Abeysinghe, J. W. Haus, J. Heikenfeld, “Agile wide-angle beam steering with electrowetting microprisms,” Opt. Express. 14, 6557-6563 (2006).
11. P. Mach, T. Krupenkin, S. Yang, J. A. Rogers, “Dynamic tuning of optical waveguides with electrowetting pumps and recirculating fluid channels,” Appl, Phys. Lett. 81, 202-204 (2002).
12. U.S. Pat. No. 6,829,415

### BACKGROUND OF THE INVENTION

Tunable optofluidic devices (TODs) [1] gain their tunability by modifying the geometry or the refractive index of a fluid interacting with light. The application of external pressure is a common method to control TODs, either by allowing an exchange of liquids having different index of refraction, or by applying a gas pressure that assists in modifying the TOD's geometry. Variety of pressure actuated TODs have been demonstrated both in free-space configuration, e.g. lenses [2], diffraction gratings [3] and switches [4], as well as in integrated on chip configuration, e.g. microring resonator (MRR) [5], dye lasers [6], photonic band gap crystals [7] and waveguides [8].

It is known to use electrowetting, based on electrical signals as a control mechanism, for tuning light propagation through an optical device [9,12]. Common features of the electrowetting technique are low power consumption and a short response time (in the millisecond regime). TODs driven by the electrowetting based techniques operate with as optical fibers [11, 12], and also with the use of liquid lenses or prisms [10].

### SUMMARY OF THE INVENTION

There is a need in the art in a novel optofluidic device that can be used in various applications requiring tuning of an electrooptical device implemented as an integrated structure.

In preferred embodiments, the present invention provides a tunable integrated electro-optical device (e.g. on chip polymer-waveguide mirroring resonator based device) in which tenability is achieved by controlling the wetting angle of a droplet that is partially or fully covering a waveguide.

According to one broad aspect of the invention, there is provided an integrated structure comprising:

at least one waveguide;

at least one fluid chamber associated with said at least one waveguide and configured and operable to selectively allow one or more droplets of said fluid from the fluid chamber to access at least a portion of the waveguide thereby selectively creating one or more fluid-waveguide interfaces and affecting the effective refractive index of the waveguide and light coupling at said one or more interface;

an electrode assembly configured and operable to induce an electric field within said at least one fluid chamber to affect the fluid-waveguide interface, thereby affecting light propagation in said waveguide and accordingly affecting optical properties of the integrated structure.

Preferably, the waveguide is formed by a core and a cladding and is adapted to enable light propagation in the core. The fluid-waveguide interface thus comprises a fluid-cladding interface.

The preferred tuning mechanism is an electro-wetting mechanism, which is induced by the electric field and affects wetting angles of each droplet thereby affecting one or more properties (e.g. dimension, shape) of the fluid-waveguide interface.

According to some embodiments, the fluid chamber has at least one fluid inlet adapted to allow the fluid droplet access to the portion of the waveguide. The inlet may be configured with respect to the waveguide(s) to affect one or more parameters/conditions of the waveguide(s) within a specific region of the waveguide structure. Such parameters/conditions include at least one of the following: an effective refractive index of the waveguide defined by an optical length of the waveguide, and a cross coupling condition (e.g. cross coupling coefficient) of the waveguide defined by a degree of optical coupling of said waveguide with another waveguide. For example, the fluid inlet may be adapted to allow the fluid droplet to cover the entire waveguide; or to access a portion of the waveguide, e.g. located within a coupling region of said waveguide with another waveguide.

According to some embodiments of the invention, the integrated structure includes a substrate carrying said at least one waveguide and said fluid chamber on a surface thereof. The electrode assembly comprises one or more pairs of electrodes (e.g. two pairs formed by three electrodes), at least one electrode of the pair having access to inside of the fluid chamber to provide electrical contact to the one or more fluid droplets.

The waveguide(s) may be located on a hydrophobic surface of the substrate thereby increasing a wetting angle of the fluid droplet contacting said substrate. Such hydrophobic surface may be formed by hydrophobic coating of a hydrophilic substrate or by manipulation of a surface energy of a hydrophilic substrate to convert its surface into a hydrophobic one.

According to another broad aspect of the invention, there is provided an integrated structure comprising:

at least one waveguide, the waveguide comprising a core and a cladding and adapted to enable light propagation in the core, said fluid-waveguide interface comprising a fluid-cladding interface;

at least one fluid chamber associated with said at least waveguide and configured and operable to selectively allow one or more droplets of said fluid from the fluid chamber to access at least one portion of the cladding thereby selectively creating a fluid-cladding interface and affecting light coupling at said interface;

an electrode assembly configured and operable to induce an electric field within said at least one fluid chamber to affect the fluid-cladding interface, thereby affecting light propagation in said core and accordingly affecting optical properties of the integrated structure.

According to yet another broad aspect of the invention, there is provided an integrated structure comprising: a dielectric substrate carrying on its first surface a layer structure defining at least one closed loop waveguide operable as a ring resonator and at least one bus waveguide optically coupled to said at least one closed loop waveguide via a coupling region between them; a patterned layer structure on said first surface of the substrate said pattern being configured to define a closed fluid cavity around at least a portion of at least one of the waveguides for accommodating at least one fluid droplet in said cavity; and an electrode assembly defining at least one pair of electrodes, at least one electrode of the pair extending into said cavity to enable electrical contact to said at least one droplet, thereby enabling electrowetting mechanism by application of an electric field within said cavity.

The invention, in its another aspect provides a method of fabricating the above-described tunable integrated structure. A dielectric substrate is provided (e.g. formed on a semiconductor wafer). The dielectric substrate is processed (e.g. by lithography) to form thereon or therein a first layer structure defining at least one waveguide, the waveguide comprising a core and a cladding and being adapted to enable light propagation in the core; and processed (e.g. by lithography technique) to form on its surface a second layer structure defining a closed fluid cavity around at least a portion of at least one of the waveguides for accommodating at least one fluid droplet in said cavity. Also, at least two electrodes are formed in a spaced-apart relationship on either one of the layers such that at least one electrode of the pair enters said cavity.

The dielectric substrate is preferably a silicon oxide, which may be thermally grown, grown by plasma enhanced chemical vapor deposition (PECVD), or formed by sputtering on a first surface of a silicon wafer. At least one electrode may be provided at opposite side of the dielectric substrate. For example, considering the substrate is located on top of a semiconductor wafer, this may be a second opposite surface of the wafer, and the electrode may be formed e.g. by doping or by a metal layer coating.

The waveguide core may be made of silicon, polymer, nitride, or oxide. The patterned layer structure may comprise Cytop layer(s).

### BRIEF DESCRIPTION OF THE DRAWINGS

In order to understand the invention and to see how it may be carried out in practice, embodiments will now be described, by way of non-limiting example only, with reference to the accompanying drawings, in which;

FIG. 1 is a schematic illustration of an example of an electro-optical integrated device according to the invention;

FIGS. 2A and 2B exemplify a schematic model of the electrowetting-actuated device of the present invention utilizing a tunable micro ring resonator, showing respectively different positions of the droplet with respect to the waveguides;

FIGS. 3A-3C, 4A-4C, 5A-5C and 6A-6C show results of the experiments conducted on the device of the present invention configured similar to that of FIG. 1, where FIGS. 3A, 4A, 5A and 6A show the transmission spectra of the device and FIGS. 3B-3C, 4B-4C, 5B-5C and 6B-6C show corresponding images of the different conditions of interaction of waveguides and droplets;

FIG. 7A shows an example of the transmission, theoretical and measured, of a microring resonator structure as a function of the applied voltage;

FIG. 7B shows calculated cross sections of the droplet inside the chamber at various actuation voltages in the graph of FIG. 7A;

FIGS. 8A and 88 shows respectively the time response of a tunable microring resonator device and an image of a droplet actuated near the coupling region between the microring resonator and the bus waveguide; and

FIG. 9 exemplifies fabrication of the integrated device of the present invention.

### DETAILED DESCRIPTION OF EXEMPLARY EMBODIMENTS

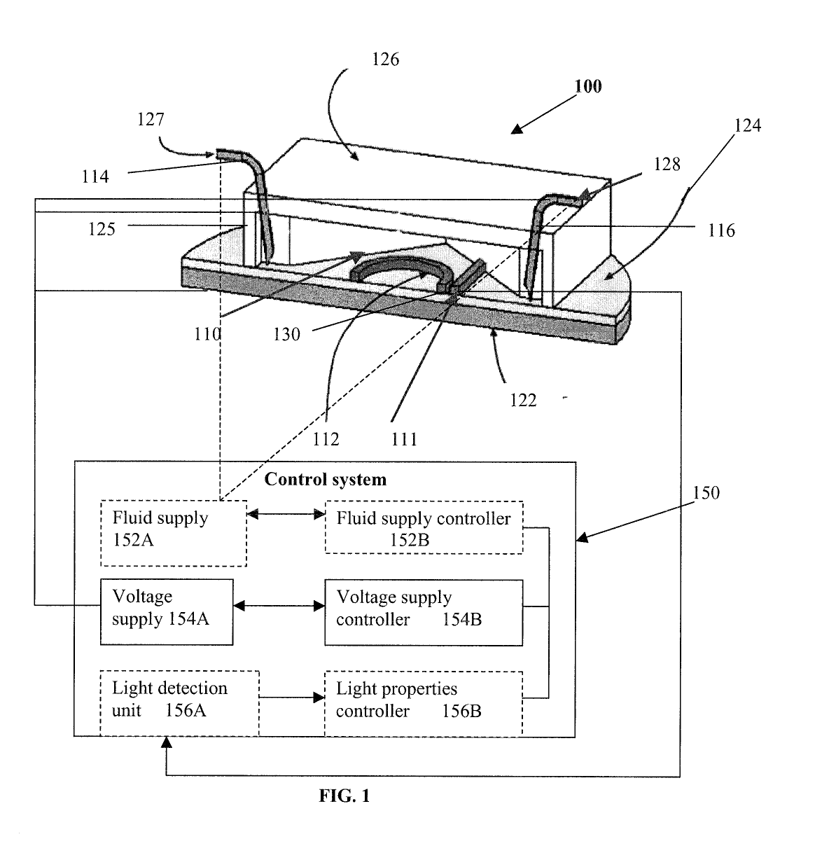

Reference is made to FIG. 1 illustrating schematically a cross-sectional view of an electro-optical device 100 according to an embodiment of the present invention. Device 100 is configured as an integrated structure. The figure shows only a half-part of the structure.

The structure 100 defines one or more waveguides, two waveguides 111, 112 being shown in the present example; one or more fluid chambers, one such chamber 110 being shown in the figure. In the present example, the same fluid chamber 110 is associated with two waveguides 111 and 112. The fluid chamber 110 operates to selectively allow access to either one of the waveguides or both of them of droplet(s) of the fluid contained in the chamber. When a droplet contacts the waveguide, a fluid-waveguide interface is created which affects effective refractive index of the waveguide within the interface thus affecting the coupling of light in/out of the waveguide through such interface as well as the light propagation in the waveguide (e.g. resonance condition of a closed loop waveguide). Accordingly, the optical properties of the device 100 are affected. As further shown in the figure, the device 100 includes an electrode assembly for inducing an electric field within the fluid chamber 110. Generally, the electrode assembly may include a pair of electrodes. In the present example, the electrode assembly defines two pairs of electrodes, formed by three electrodes 122, 114, 116, to apply electric fields to different regions of the structure. The electric field affects the fluid-waveguide interface located within the respective electric field region. This affects light propagation in the waveguide and thus the optical properties of the device 100.

In the present example, the fluid chamber 110 has a walls' structure 125 and a cover 126 attached to the walls' structure 125 by bonding, as will be described more specifically further below. The chamber 110 has inlet/outlet ports 127, 128, for flowing the fluid into and out of the chamber. In the present example, the electrodes 114, 116 are associated with the inlet/outlet ports 127, 128, i.e. the latter is made of an appropriate electrically conductive material. Waveguides 111, 112 are defined, by lithography (e.g. photolithography) or ion bombardment technique, on a substrate 124 (e.g. 2 μm-thickness Thermal Silicon Oxide), interfacing on its opposite side with electrode 122.

The waveguide 111, 112 typically has a core and a cladding, which are not specifically shown. The core and cladding are configured to provide the light confinement and propagation within the core. It should be understood that the core and cladding (their thicknesses and material compositions) define together an effective refractive index of the waveguide determining the light coupling into and out of the waveguide and in between the core and the cladding and the light propagation in the core (e.g. the resonance frequencies of the resonating waveguide).

As further shown in the figure, the device 100 is associated with a control system 150. The control system 150 typically includes a computer system including inter alia such utilities as data input and output, processor, memory, etc. The control system also includes an electric field source (voltage supply) 154A connectable to the electrode assembly in the integrated structure 100 and having its associated voltage supply controller 154B. Optionally, the control system also includes a fluid supply unit (e.g. pump) 152A connectable to inlet/outlet ports 127, 128 in the integrated structure and associated with a fluid supply controller 152B operable for controlling the provision of fluid droplets to the chamber 110.

Preferably, the control system 150 includes a controller 156B configured and operable for controlling the light properties of a waveguide structure (i.e. of the waveguides 111, 112 and interaction (coupling) between them). The controller 156B is associated with a light detection unit 156A (e.g. located at, or connected to a light output port of the device via an appropriate light guide). This light properties controller 156B is configured to provide feedback signals to the voltage supply controller 154B and optionally to the fluid supply controller 152B for, respectively, adjusting the wetting angles of the droplets and the amount of fluid (the number and volume of the droplets) within the chamber, to thereby control/maintain the desired properties of light propagation through the device 100. It should be understood that controllers 152B, 154B and 156B, and possibly also a light detection unit 156A, might be implemented as an integrated circuit being “on-chip” in the with the integrated structure 100.

In the present example, the device 100 is configured and operable as a spectral filter, and includes a closed loop waveguide 112 (presenting a so-called “ring resonator”) and an input-throughput waveguide 111 (presenting a so-called “bus waveguide”). Waveguides 111 and 112 have a light coupling region 130 between them. The construction and operation of such a ring-resonator based spectral filter are known per se and need not be described in details, except to note the following. The spectral resonance frequencies of the ring resonator are associated with the optical length of the ring waveguide, which is in turn associated with the effective refractive index of the ring waveguide (e.g. its cladding). The amount of light that can be affected by the ring resonator is defined by a degree of optical coupling between the bus waveguide and the ring waveguide, which coupling is dependent inter alia on a difference in their refractive indices (i.e. those of their claddings) and optical modes for which the waveguides are configured (resonance frequency in the case of a resonating waveguide). Thus, tuning of the spectral filtering condition of the waveguide structure (formed by waveguides 111, 112) can be achieved by affecting at least one of the optical length of the ring waveguide 112 and the degree of coupling between the waveguides 111, 112, which, for a given size of a region of coupling between the waveguides, can be obtained by appropriate manipulation of either one or both of the refractive indices of the claddings of the waveguides 111, 112.

A change in the refractive index is induced by the interaction of the waveguide with the fluid from the fluid chamber 110. As indicated above, the chamber 110 is configured for accommodating one or more droplets of fluid therein in a manner to selectively provide (i.e. when tuning is required) access of the droplet(s) to the cladding of at least one of waveguides 111 and 112. It should be noted that according to the invention, coupling between the cladding of a portion of a waveguide and the fluid generally affects the optical properties of the cladding at the interface region at which the cladding interfaces the fluid (i.e. fluid-cladding interface region). More specifically, the effective refractive index of the cladding with the fluid drop may be different at this interface region as compared to that of a non interfacing region (region at which the cladding does not interface the fluid drop). Accordingly, the effective refractive index of the waveguide portion associated with said interface region is affected. Additionally or alternatively the light transmission properties of the cladding at the fluid-cladding interface region is different with respect to that of the non interfacing region. This might affect the optical coupling between two adjacent waveguides.

The present invention utilizes control of the wetting properties of a fluid/droplet accommodated within the chamber to controllably vary the configuration (e.g. the location shape and area) of the interface between the fluid and one or more waveguides (claddings). It should be understood that considering for example FIG. 1, the fluid cladding interface may be created within the coupling region 130 between the two waveguides 111, 112 to thereby simultaneously affect the light propagation in the two waveguides.

Preferably, an electro-wetting mechanism is used to affect the light propagation properties of the waveguide(s) to thereby implement the tuning effect. The principles of the electro-wetting mechanism are known per se and therefore need not to be described in details. In the present invention, however, the electro-wetting mechanism is implemented within the integrated structure, and the fluid chamber is thus formed to be an integral part of such multi-layer structure. Thus, the wetting angle of the droplet in the fluid chamber is electrically controlled to thereby control the dimension(s) of the interface between the fluid droplet and the waveguide. To this end, the electrode assembly is appropriately configured and operable to induce an electric field within said the fluid chamber 110. As indicated above, in the present example the electrode assembly includes electrodes 122, 114 and 116 which are configured to affect the fluid-cladding interfaces at two different regions of the waveguides 111 and 112 thereby affecting light propagation in these regions of the waveguides (e.g. in there cores) and the coupling between the waveguides.

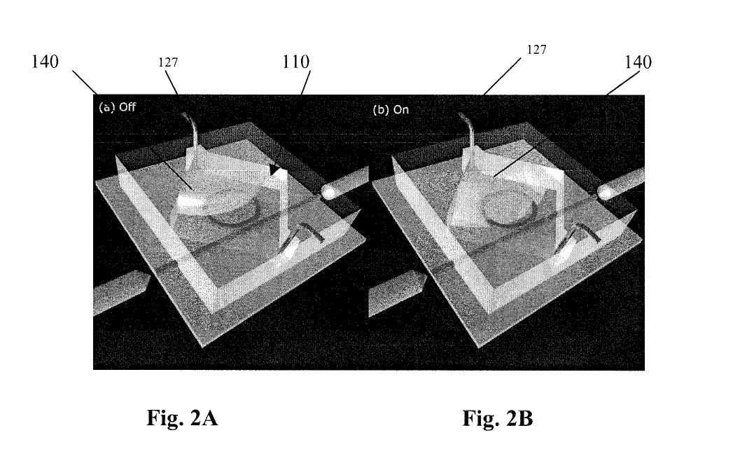

Reference is made to FIGS. 2A and 2B showing a schematic model of the electrowetting-actuated device of the present invention utilizing a tunable micro ring resonator, similar to that described above with reference to FIG. 1. This model is based on the so-called electrowetting-on-dielectric (EWOD) technique. As shown in both figures, a droplet 140 is introduced into chamber 110 through inlet 127 and brought in contact with the ring-waveguide 112 within a portion of its cladding. The droplet is typically larger than the waveguide lateral dimension and therefore contacts also the substrate 124 in the vicinity of the outlet 127. Substrate 124 (Thermal Silicon Oxide) has hydrophobic surface (e.g. being that of a hydrophobic coating or resulting from a change in a surface energy applied to the initially hydrophilic surface of the substrate). The droplet 140 is also kept contacting electrode 114, which is achieved by implementing the electrode 114 in the inlet 127. FIG. 2A shows an Off state, corresponding to no electric field creation by the electrode assembly. Accordingly the contact angle between the droplet 140 and the hydrophobic surface is high, and the degree of contact between the droplet and the waveguide is relatively small. FIG. 2B shows an On state: the electric field is applied, the contact angle is decreased and the droplet covers a larger portion of the waveguide's surface (the degree of coupling is increased), thus changing the transmission spectrum of the ring-resonator 112. It should be understood that various intermediate states are also possible by controlling the voltage applied to the structure.

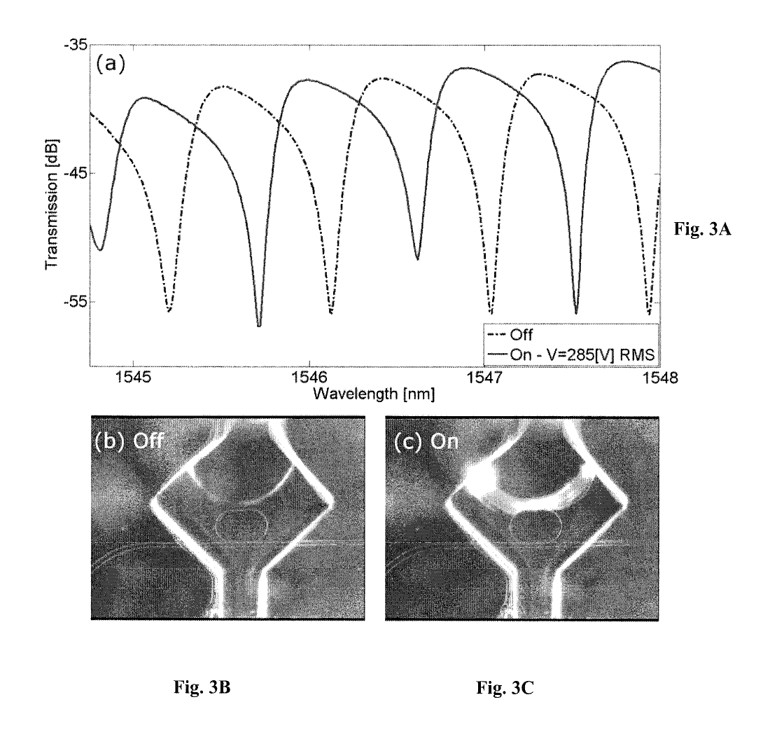

The following are experimental results conducted on the device of the present invention. FIGS. 3A, 4A and 5A show transmission spectrum of the device, i.e. of the microring resonator, while FIGS. 3B-3C, 4B-4C and 513-5C show images of the different conditions of interaction of waveguides and droplets.

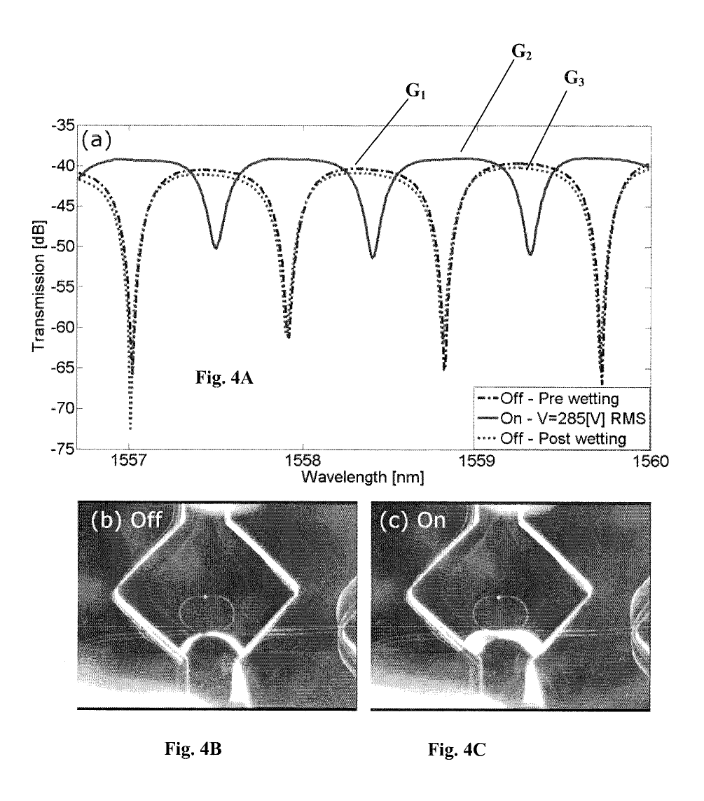

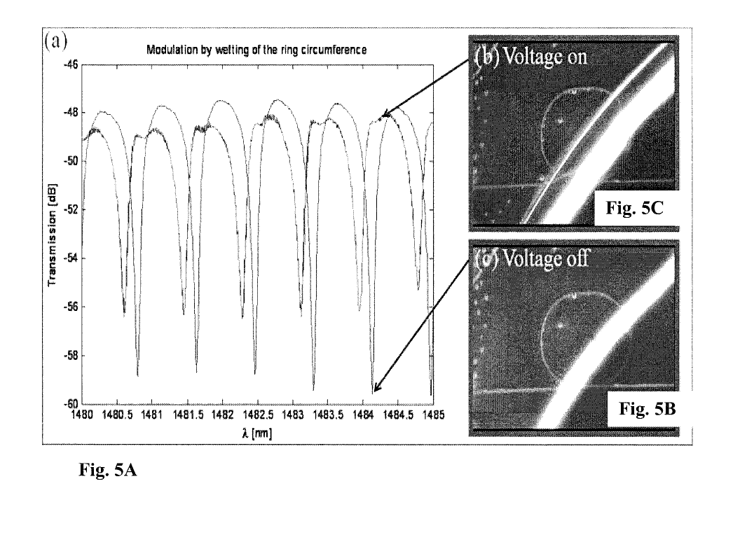

In these experiments, a microliter syringe was used to inject a droplet through one of the inlets, towards the vicinity of the microring resonator that was positioned within the fluid chamber and had to be tuned. The syringe was filled with a 0.1M solution of NaSO4 in water. In the examples of FIGS. 3A-3C and 5A-5C tuning of the device via the ring circumference was carried out, and in the example of FIGS. 4A-4C the tuning was applied to the coupling region between the ring- and bus-waveguides.

A TE (in plane) polarized light was coupled from a tunable laser (Agilent 81680A) to the input facet of the bus waveguide 111 using a polarization maintaining tapered fiber with a mode size of 2.5 μm, in a butt coupling configuration. An identical tapered fiber was used to collect light from the output facet of the waveguide. Light was detected by an InGaAs photodetector (HP 81634A).

FIG. 3A illustrates the transmission spectrum of a ˜200 μm-radius microring resonator 112 in the two states, one being called Off state (dashed curve) and corresponding to the lack of contact between the droplet and the microring waveguide, and the other being On state (solid curve) characterized by the contact between the droplet and the microring waveguide.

These two conditions of interaction between the droplet and the waveguide are shown in FIGS. 3B and 3C. The contact between the droplet and the waveguide resulted from the application of an electric field to the droplet via electrodes 114 and 122 (shown in FIG. 1), achieved by the application of 285Vrms 1 kHz sinusoidal AC voltage. Thus, this example demonstrates modulation of the microring radius. The front end of the droplet is located ˜20 μm away from the microring, while in the Off state. In the On state, the wetting angle is reduced and the droplet comes into contact with a ˜330 μm length section of the microring's circumference from the outer side. The application of the electric field causes a redshift of about 0.5 nm in the transmission spectrum, this may for example result in a 19 dB modulation in the light transmission at wavelength of ˜1548 nm.

The obtained redshift of 0.5 nm agrees with the theoretical prediction calculated as:

$$Δ λ = λ \frac{Δ {n}_{eff} \cdot γ}{{n}_{eff}} = 1550 \frac{0.005 \cdot 0.09963}{1.5} = 0.515 nm \qquad ( 1 )$$

where λ is the wavelength (1550 nm), n_{eff} is the effective refractive index of the microring waveguide (1.5), Δn_{eff} is the change in the effective refractive index of the waveguide resulted from a change in the medium of the upper cladding of the waveguide (at the side of the droplet) from air to water (this value was found to be 0.005 by using the beam propagation method, and γ is the relative surface area (i.e. contact region) of the microring waveguide over which the modulation is taking place. This relative surface area is determined as:

$$γ = \frac{{A}_{cross} \cdot {L}_{water}}{{L}_{total}} = \frac{0.5 \cdot 330}{1656} = 0.09963 \qquad ( 2 )$$

where A_{cross} represents the relative amount of the waveguide's cross section that is covered by the droplet (the inventors estimated A_{cross} to be about 0.5 in this experiment), L_{water} is the circumferential length (330 μm) of the microring waveguide that is in contact with the droplet, and Lₜₒₜₐₗ is the overall length of the microring's circumference (1656 μm).

In the experiment represented by FIGS. 4A-4C, the droplet was injected from the inlet at the opposite side of the microring (via the inlet 128, being electrode 116, in FIG. 1), to modulate the cladding of the microring waveguide in the coupling region between the microring waveguide 112 and the bus waveguide 111. FIG. 4A shows the transmission spectrum in the Off and the On states, as described above. Three graphs are shown, graph G₁ corresponds to the condition before application of the electric field (initial Off state or pre-wetting state) during which there is no contact between the droplet and the waveguides, graph G₂ corresponds to the condition resulting from the application of the electric field (On state), and graph G₃ corresponds to the post-wetting Off state created immediately after the application of the electric field. By observing the resonance around 1557 nm wavelength, a drop in the extinction ratio, was noticed to be from ˜25 dB (the difference from ˜−40 dB to ˜−65 dB) to about 12 dB (the difference from ˜−39 dB to ˜−51 dB). Similar trend was noticeable also for the other resonant deeps. To verify the repeatability of operation, the voltage was turned off and the spectrum was measured once more. The post wetting results were almost identical to the pre-wetting results.

The drastic change in the extinction ratio is due to the significant change in the coupling coefficient between the bus waveguide and the microring waveguide. As a result, the mismatch between internal loss in the mirroring waveguide and the transmission coefficient increase, leading to a reduction in a modulation depth, as expected from the transmission function:

$$T = \frac{{α}^{2} + {\vert t \vert}^{2} - 2 α \vert t \vert cos θ}{1 + {α}^{2} {\vert t \vert}^{2} - 2 α \vert t \vert cos θ} \qquad ( 3 )$$

where α is the amplitude loss coefficient per round trip (α=1 for a lossless microring waveguide), t is the through coupling coefficient, and θ is the phase shift per round trip.

The transmission of the microring waveguide is minimum at the resonance condition, θ=2πN. The transmission at the resonance approaches zero at a condition of critical coupling, when the values of α and t are closely matched. Therefore, the extinction ratio can be controlled by changing either t or α, or both of these parameters.

To estimate the degree of match between α and t in the Off and On states, the 1^{st} resonance deep (graph G₁ in FIG. 4A) was fitted to Eq. 3. The inventors have found the values of α and t in the Off state (post wetting) to be closely matched with the corresponding values of 0.590 and 0.576, respectively. On the other hand, by fitting the On state, the inventors have found values of 0.5629, and 0.7104 for α and t respectively. Although the increase in t seems to be counter intuitive, because higher refractive index of the upper cladding is expected to increase in cross coupling (resulting in a decrease in t), FIG. 4C shows that the droplet is in contact only with the outer boundary of the bus waveguide 111. As a result, the waveguide mode is pulled away from the microring, resulting in a lower cross coupling and a higher value of t. This partial coverage of the waveguide cross section is also in agreement with the value of γ that was used to calculate the expected redshift in FIG. 3A.

In the example of FIG. 4A, similar to the above example of FIG. 3A, a redshift in the resonant wavelength of about 0.5 nm is noticeable. This is again due to the increase in the effective refractive index of the microring waveguide 112 resulting in an increase in the optical path length of the microring.

Independent control over the resonant wavelength and the modulation depth is feasible via the realization of two droplets, one tuning the coupling region (as in the example of FIGS. 4A-4D) and the other tuning the ring circumference (as in the example of FIGS. 3A-3C). For example, in order to control the modulation depth without experiencing a shift in the resonance frequency, two droplets can be used operating in a compensation mode, where the droplet tuning the microring circumference is operated in a reverse mode, i.e. the voltage applied to this droplet is reduced with the increase of voltage applied to the other droplet modulating the coupling region, thereby maintaining the optical length of the microring substantially contact while manipulating the degree of coupling between the microring and bus waveguides.

FIGS. 5A-5C show tuning of the transmission spectrum (FIG. 5A) of the microring waveguide in the Off state (zero voltage on the droplet) and the On state (285Vᵣₘₛ AC voltage on the droplet), where the droplet in both Off and On states covers the coupling region between the microring and bus waveguides (FIGS. 5B and 5C). Thus, the effective refractive index of the waveguides within the coupling region is not affected by the application of voltage, and the application of voltage results solely in a redshift of about 0.2 nm in the transmission spectrum of the microring waveguide, leading to a 11 dB modulation in the light transmission (for the wavelength indicated in the figure).

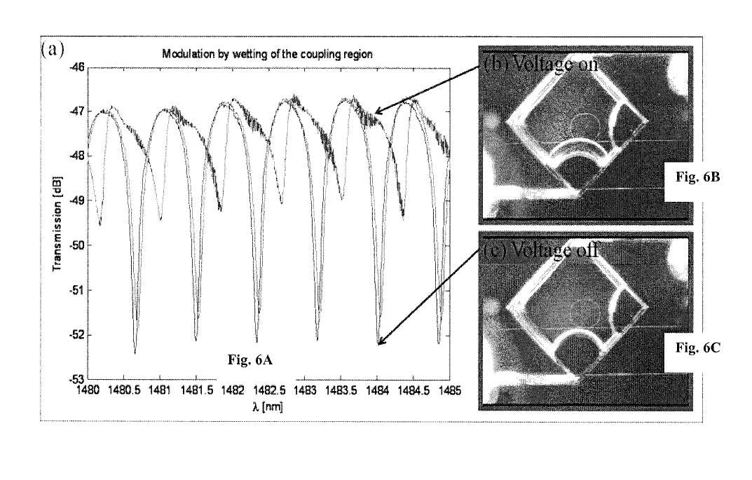

FIGS. 6A-6C show experimental results generally similar to the example of FIGS. 4A-4C. Here, in order to allow tuning of the coupling strength of the microring waveguide with the bus waveguide, the external pressure (feeding the droplet into and through the fluid chamber) is adapted such that the front end of the droplet is almost in contact with the coupling region. FIG. 6A shows the transmission spectrum of the microring resonator waveguide in the Off and the On state corresponding to the droplet position of FIGS. 6C and 6B respectively. The depths of the resonant peaks in the On state are only 2-3 dB, in contrast to the 5-6 dB depth in the Off state. This might be because the coupling coefficient between the bus waveguide and the microring waveguide increases significantly. As a result, the mismatch between internal loss in the microring waveguide and the coupling loss increases, resulting in a reduction in the modulation depth. Here again, in addition to the significant change in modulation depth, a shift in the resonant wavelength is also noticeable. This is because the optical path length in the microring waveguide is increased. Independent control over the resonant wavelength and the modulation depth can be achieved via the realization of two droplets, one covering the ring circumference and the other the coupling region.

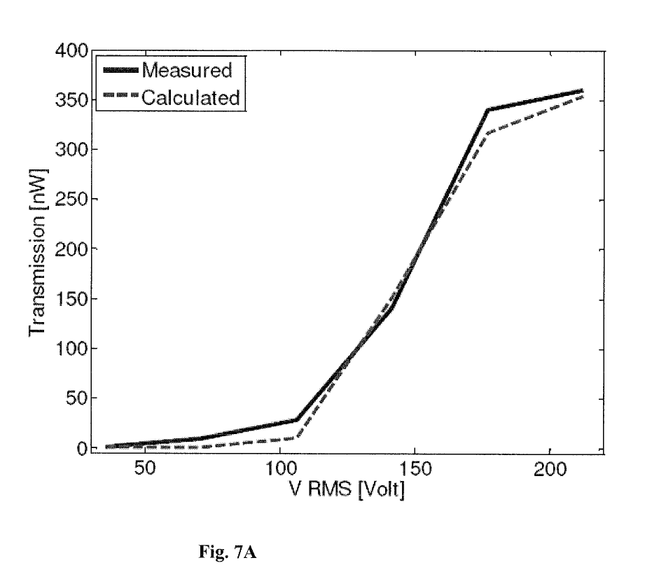

Reference is made to FIG. 7A showing the transmission of the microring resonator structure as a function of the applied voltage, corresponding to the measured transmission through the bus waveguide (solid curve) and calculated/theoretical data (dashed curve). The transmission is plotted starting at a resonant wavelength at a condition where the microring resonator waveguide partially covered by a droplet. In this experiment, a microring radius of 100 μm was used, and the transmission vs. voltage was measured at a fixed wavelength around 1550 nm. The laser wavelength was tuned to fall within one of the resonances of the MRR, at which the transmission of the device is close to zero. Then, the voltage was raised up to 212 volts RMS. As the applied field (applied voltage) increases, the droplet spreads and covers a larger portion of the microring's circumference, resulting in a shift in the microring resonant wavelength and in an increase in the light transmission. This result can be explained by a model developed by the inventors that includes the following:

The droplet angle vs applied field (voltage) on the device substrate was measured and a fit to Lipmann equation was found:

$$cos θ = cos {θ}_{0} + \frac{C}{2 γ} {V}^{2} \qquad ( 4 )$$

From the fitting, it was obtained that (C/2γ)=1.33480·10⁻⁴ V⁻², where C is the surface capacitance and γ is the surface tension of the droplet in air. This result is lower by a factor of 1.17 than the theoretical value of this coefficient calculated from the known values of water surface tension in air and permittivity of silicon dioxide (substrate) and Cytop (cover material of the fluid chamber).

The wetting angle was used to calculate the droplet's front line, with the constrain of a constant droplet height (resulted by the chamber's configuration), droplet shape and constant volume. These considerations are demonstrated in FIG. 7B showing calculated cross sections of the droplet inside the chamber at each actuation voltage. The top contact angle (being the contact angle with the cover of the fluid chamber) is constant at 109.2° and the bottom contact angle (being the contact angle with the substrate) changes with voltage from 109.2° down to 84.4°. A total advancement of 58.3 μm in the droplet frontline can be seen.

Using the droplet frontline positions and the microring geometry, the inventors have found the lengths of the waveguide portion covered with water as a function of the applied voltage and thus the redshift in the resonant wavelengths, according to Eq. 1 above. The redshift values and a typical microring resonator transmission function were then used to calculate the transmission values. The parameters of the microring resonator transmission function were chosen to obtain good fit of the model to the experimental results in FIG. 7A.

As can be seen, the transmission curve is not linear. While Eqs. 3 and 4 imply a nonlinear relation between the transmission and voltage, the nearly flat transmission was obtained for voltages values up to 100 volts. This might be caused by that the droplet is pinned on the ring till a certain threshold voltage is reached. The inventors modeled this by introducing a threshold voltage such that the effective electrowetting voltage is determined by the applied voltage less the threshold voltage. This threshold characteristic is in agreement with the transmission results as shown in FIG. 7A.

The inventors also measured the time response of the device. To this end, the sinusoidal AC signal of 1 kHz was modulated to give a single sinusoidal period every 100 periods (resulting in a frequency of 10 Hz). The output optical signal was detected by a photodetector (New Focus 2011-FC), with a response time of 2 μsec, that was connected to an Oscilloscope. The measured rise time is about 200 μsec and fall time is about 700 μsec. The use of smaller droplets would further reduce the time response of such devices.

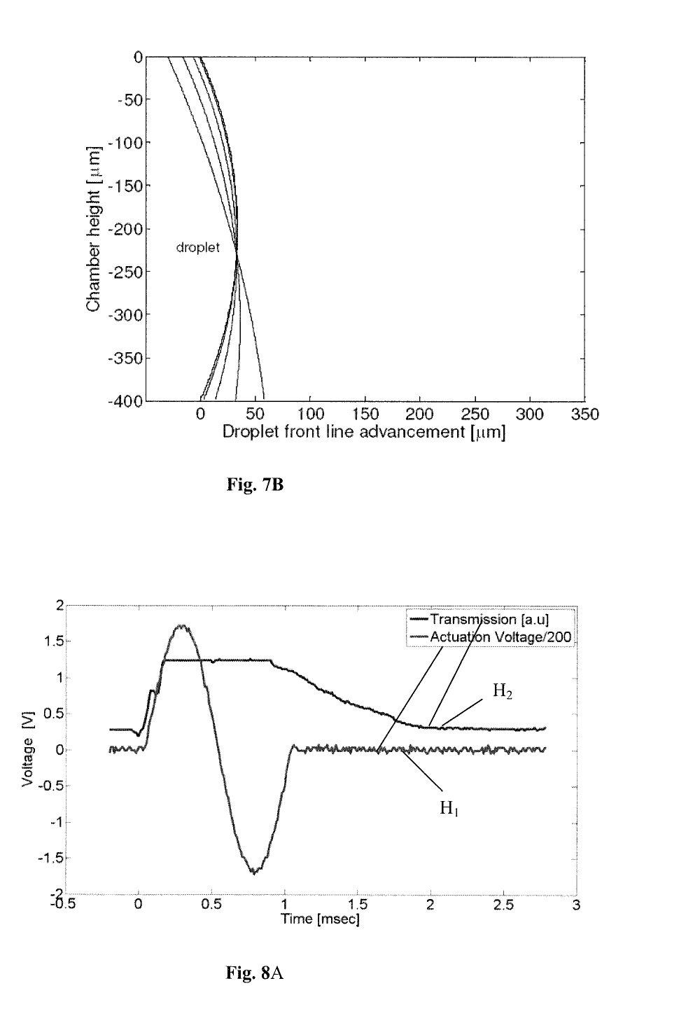

Reference is made to FIGS. 8A and 8B showing respectively the time response of a tunable microring resonator device like that of FIG. 1 and an image of a droplet actuated near the coupling region between the microring resonator and the bus waveguide. In this experiment, the tuning of an on-chip (integrated structure) microring resonator device via the electrowetting-on-dielectric technique was shown. FIG. 8A shows two graphs H₁ and H₂ corresponding to a single sinusoidal period of the actuation voltage (H₁, V/200) and to the recorded optical transmission (H₂, in arbitrary voltage units).

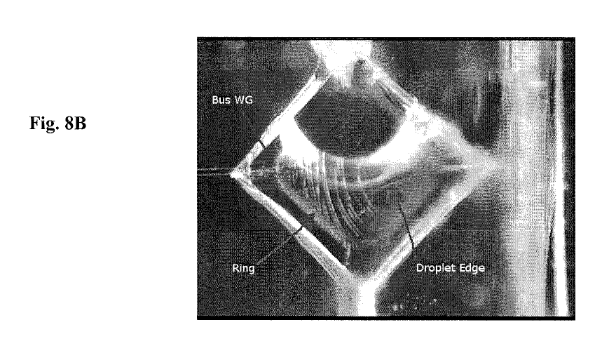

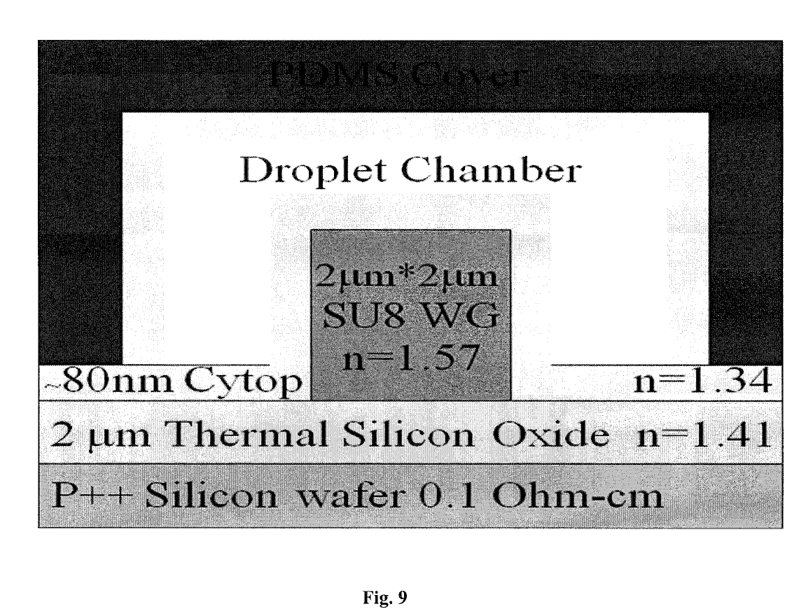

FIG. 9 exemplifies fabrication of the device 100 of FIG. 1. Device 100 is fabricated as an integrated structure. FIG. 9 shows a cross-sectional view of such structure. Thus, device 100 includes two waveguides, only one of them, e.g. bus waveguide 111, being shown in the figure, a fluid chamber 110 located around a portion of waveguide 111 to thereby allow access of fluid droplet(s) to this waveguide portion to create a fluid-waveguide interface, and an electrode assembly including a bottom electrode (122 in FIG. 1) located below the waveguide structure.

In this example, to fabricate the device 100 an n⁺⁺ silicon wafer 122 (serving as a bottom electrode) is provided, and then a 2 μm layer of thermally grown silica (serving as a substrate 124) is created on top of wafer 122. Photolithography is applied to silica layer 124 to define the SU8 waveguides 111 (and 112 which is not shown here). It should be noted that in this example, the doped silicone electrode was chosen rather than a metal electrode because it enables to grow the thermal silicon dioxide layer to form a high quality dielectric insulator. In different experiments, the radii of the microring resonator was 200 μm and 100 μm and a race track length (extended strait length of the waveguide at the coupling region) was 200 μm; the waveguide cross section dimensions were 2 μm*2 μm; the coupling distance between the bus waveguide and the microring waveguide was designed to be 1 μm.

A microfluidic chamber of 1.5*1.5*0.4 mm in dimensions, and microfluidic channels (presenting inlet and outlet channels) connected to this chamber are defined in a Polydimethylsiloxane (PDMS) by soft lithography. The PDMS is bonded to the silica substrate by applying pressure, where a Cytop is spun on both sides (PDMS and silica substrate) and used as a bonding material. The PDMS and the silica substrate are pressed together at 120° C. for one hour. In addition to being a good bonding material, Cytop also serves as a hydrophobic layer to increase the wetting angle of the droplet in the Off (zero voltage) state. The thickness of the dielectric insulating layer 124 was chosen to be 2 μm (so as to be large enough to avoid leakage of optical radiation into the silica substrate and to be thin enough to reduce the voltage required for electrowetting).

Thus, the present invention provides a novel approach for tunable on-chip (integrated) electro-optical devices, such as microring based resonators. This approach can be used for the realization of a variety of optofluidic integrated tunable optical devices actuated by electrowetting (electrowetting-on-dielectric), with the advantages of high effective refractive index contrast that allows substantial optical modulation, low power consumption and no heating. The invented technique may be used in biosensing and monitoring applications, as well as in devices requiring complex and precise optical tuning by using multiple miniature droplets.

1. An integrated structure comprising:
at least one waveguide
at least one fluid chamber associated with said at least one waveguide and configured and operable to selectively allow one or more droplets of said fluid from the fluid chamber to access at least a portion of the waveguide thereby selectively creating one or more fluid-waveguide interfaces and affecting an effective refractive index of the waveguide and light coupling at said one or more interface;
an electrode assembly configured and operable to induce an electric field within said at least one fluid chamber to affect the fluid-waveguide interface, thereby affecting light propagation in said waveguide and accordingly affecting optical properties of the integrated structure.

2. The integrated structure of claim 1, wherein said at least one waveguide comprises a core and a cladding and adapted to enable light propagation in the core, said fluid-waveguide interface comprising a fluid-cladding interface.

3. The integrated structure of claim 1, wherein said electric field induces an electro-wetting mechanism that affects wetting angles of each of said one or more droplets thereby affecting a dimension of the fluid-waveguide interface.

4. The integrated structure of claim 1, wherein the fluid chamber comprises at least one fluid inlet adapted to allow the fluid droplet access to the portion of the waveguide located for affecting at least one of the following parameters: an effective refractive index of the waveguide defined by an optical length of the waveguide, and a cross coupling coefficient of the waveguide defined by a degree of optical coupling of said waveguide with another waveguide.

5. The integrated structure of claim 1, wherein the fluid chamber comprises at least one fluid inlet adapted to allow the fluid droplet access to the portion of the waveguide located within a coupling region of said waveguide with another waveguide.

6. The integrated structure of claim 1, wherein said at least one waveguide is located on a hydrophobic surface of a substrate thereby increasing a wetting angle of the fluid droplet contacting said substrate.

7. The integrated structure of claim 1, comprising a substrate layer carrying said at least one waveguide and said fluid chamber thereon, said electrode assembly comprising at least one pair of electrodes, at least one electrode of the pair of the electrodes having access to inside of the fluid chamber to provide electrical contact to the one or more fluid droplets.

8. The integrated structure of claim 2, wherein said electric field induces an electro-wetting mechanism that affects wetting angles of each of said one or more droplets thereby affecting a dimension of the fluid-waveguide interface.

9. The integrated structure of claim 2, wherein the fluid chamber comprises at least one fluid inlet adapted to allow the fluid droplet access to the portion of the waveguide located for affecting at least one of the following parameters: an effective refractive index of the waveguide defined by an optical length of the waveguide, and a cross coupling coefficient of the waveguide defined by a degree of optical coupling of said waveguide with another waveguide.

10. The integrated structure of claim 2, wherein said at least one waveguide is located on a hydrophobic surface of a substrate thereby increasing a wetting angle of the fluid droplet contacting said substrate.

11. The integrated structure of claim 2, comprising a substrate layer carrying said at least one waveguide and said fluid chamber thereon, said electrode assembly comprising at least one pair of electrodes at least one of the electrodes in the pair of electrodes having access to inside of the fluid chamber to provide electrical contact to the one or more fluid droplets.

12. An integrated structure comprising:
at least one waveguide, the waveguide comprising a core and a cladding and adapted to enable light propagation in the core, said fluid-waveguide interface comprising a fluid-cladding interface;
at least one fluid chamber associated with said at least waveguide and configured and operable to selectively allow one or more droplets of said fluid from the fluid chamber to access at least one portion of the cladding thereby selectively creating a fluid-cladding interface and affecting light coupling at said interface;
an electrode assembly configured and operable to induce an electric field within said at least one fluid chamber to affect the fluid-cladding interface, thereby affecting light propagation in said core and accordingly affecting optical properties of the integrated structure.

13. An integrated structure comprising: a dielectric substrate carrying on its first surface a layer structure defining at least one closed loop waveguide operable as a ring resonator and at least one bus waveguide optically coupled to said at least one closed loop waveguide via a coupling region between them; a patterned layer structure on said first surface of the substrate said pattern being configured to define a closed fluid cavity around at least a portion of at least one of the waveguides for accommodating at least one fluid droplet in said cavity; and at least one pair of electrodes, at least one electrode of the pair extending into said cavity to enable electrical contact to said at least one droplet, thereby enabling electrowetting mechanism by application of an electric field within said cavity.

14. The integrated structure of claim 13, wherein said dielectric substrate is located on a first surface of a semiconductor wafer.

15. The integrated structure of claim 14, wherein said substrate is a silicon oxide formed on the first surface of a silicon wafer by one of the following techniques: thermal growth; plasma enhanced chemical vapor deposition (PECVD); sputtering.

16. The integrated structure of claim 13, wherein the waveguide core is silicon, polymer, nitride, or oxide.

17. The integrated structure of claim 13, comprising an electrode located at a side of the dielectric substrate opposite to said first surface.

18. The integrated structure of claim 14, comprising an electrode formed on a second opposite surface of the semiconductor wafer.

19. The integrated structure of claim 18, wherein said electrode is formed on said second opposite surface of the semiconductor wafer by either a metal layer coating or doping.

20. The integrated structure of claim 13, wherein said patterned layer structure comprises Cytop layers.

21. A method of fabricating a tunable integrated structure, the method comprising:
providing a dielectric substrate;
processing said dielectric substrate to form a first layer structure carried by said substrate and defining at least one waveguide, the waveguide comprising a core and a cladding and being adapted to enable light propagation in the core; and to form on a first surface of the dielectric substrate a second layer structure defining a closed fluid cavity around at least a portion of at least one of the waveguides for accommodating at least one fluid droplet in said cavity;
forming at least two electrodes accommodated in a spaced-apart relationship on either one of the layers such that at least one electrode of the pair enters said cavity.

22. The method of claim 21, comprising forming said dielectric substrate on a first surface of a semiconductor wafer.

23. The method of claim 22, wherein said semiconductor wafer is a silicon wafer and said substrate is a silicon oxide formed on the first surface of the silicon wafer by one of the following: thermal growth; plasma enhanced chemical vapor deposition (PECVD) on the first surface of a silicon wafer; and sputtering.

24. The method of claim 21, wherein the waveguide core is made of at least one of the following materials: silicon, polymer, nitride, or oxide.

25. The method of claim 22, comprising forming an electrode on a second opposite surface of the semiconductor wafer by using metal coating or doping.

26. The method structure of claim 13, wherein said patterned layer structure comprises Cytop layers.

27. A method of fabricating a tunable integrated structure of claim 12, the method comprising:
(i) providing a semiconductor wafer, and thermally growing on a first surface thereof a dielectric substrate layer, a second opposite surface of the semiconductor wafer being configured as a bottom electrode;
(ii) applying a first lithography technique to a surface of the dielectric substrate layer to form thereon a first layer structure defining at least one waveguide, the waveguide comprising a core and a cladding and adapted to enable light propagation in the core;
(iii) applying a second lithography technique to the surface of the dielectric substrate layer to form a second layer structure defining a closed fluid cavity around at least a portion of at least one of the waveguides for accommodating at least one fluid droplet in said cavity;
(iv) forming at least one electrode entering said cavity.
